(19) United States
(12) Patent Application Publication
(10) Pub. No.: US 2007/0004181 A1
(43) Pub. Date: Jan. 4, 2007

(54) Method for fabricating semiconductor device

(75) Inventors: Yong-Tae Cho, Kyoungki-do (KR); Hae-Jung Lee, Kyoungki-do (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Hynix Semiconductor Inc.

(21) Appl. No.: 11/363,913

(22) Filed: Feb. 27, 2006

(30) Foreign Application Priority Data
Jun. 30, 2005 (KR) 2005-0058711

(51) Int. Cl. H01L 21/326

(52) U.S. Cl. 438/467; 257/E23.149

(57) ABSTRACT

A method for fabricating a region in which a fuse is formed is provided. The method includes forming a first insulation layer over a substrate, forming a plurality of fuses over the first insulation layer, forming a second insulation layer to cover the fuses, forming an etch stop layer over the second insulation layer, forming a metal layer over a predetermined portion of the etch stop layer, forming a third insulation layer to cover the metal layer, performing a pad/repair process on the third insulation layer until the metal layer and the etch stop layer are exposed, and selectively removing the exposed portion of the etch stop layer and the second insulation layer.

### FIELD OF THE INVENTION

The present invention relates to a method for fabricating a semiconductor device; and more particularly, to a method for fabricating a region in which a fuse is formed.

### DESCRIPTION OF RELATED ARTS

During fabricating a semiconductor memory device, if at least one defect is found among many micronized cells, the semiconductor memory device is considered as a defective product since the semiconductor memory device cannot serve a role as a memory. However, although the defect is found only in predetermined cells inside the memory, if the whole memory device is discarded as the defective product, it is a very inefficient in terms of yields of products.

Accordingly, the defective cells are replaced by using redundancy cells previously installed inside the memory device, and thus, the whole memory can be used. In this way, it is possible to improve yields of products.

As for a repair process using redundancy cells, a spare row array and a spare column array are installed every predecided cell array beforehand so that, defective memory cells generating defects are replaced by spare memory cells in a row/column unit.

In more detail, if the defective memory cells are selected through a test after a memory device is formed over a wafer, a program changing an address signal corresponding to the defective memory cells to an address signal corresponding to the redundancy cells is installed in an internal circuit. Accordingly, when the program is actually performed, if the address signal corresponding to a defective line is inputted, the redundancy cells are selected instead of the defective cells.

A method most widely used for replacing defective memory cells by redundancy memory cells is a method for burning out a fuse by using a laser beam. An interconnection line burned out by a scanning of the laser beam is called a fuse, and a region in which the fuse is burned out and a portion surrounding the aforementioned region are called a fuse box.

The fuse is not formed by using a separate interconnection line but by selecting one of the interconnection lines applied to a conventional circuit in the fuse box.

Traditionally, the fuse has been formed with a conductive layer comprising word lines or bit lines. However, since too many layers are formed in an upper portion of the word lines or the bit lines, as a semiconductor device has been highly integrated, it becomes very difficult to form the fuse box.

In order to solve the above described limitations, an electrode layer of a capacitor formed in a higher portion than the word lines or the bit lines can be used. However, in this case, it is also difficult to form the fuse box since a number of insulation layers are placed in an upper portion of the electrode layer. Accordingly, a metal interconnection line is used as the fuse.

Meanwhile, an etching process for forming the fuse box, and the other etching process for forming a pad to input and output a signal of the semiconductor device are performed in one etching process. It is called a repair/pad etching process.

FIG. 1 is a cross-sectional view illustrating a conventional method for fabricating a semiconductor device. FIGS. 2 to 5 are micrographic images of scanning electron microscopy (SEM) illustrating limitations caused by the conventional method.

As shown in FIG. 1, a structure 11 including a plurality of insulation layers and a plurality of conductive layers is formed over a substrate 10, and a plurality of fuses 12 are formed thereon. Herein, the fuses 12 are not formed using a separate layer. Instead, the fuses 12 are formed using a first metal interconnection line which processes an operation of a memory device.

Next, a first inter-layer insulation layer 13, a second inter-layer insulation layer 14, a second metal interconnection line 16, and a third inter-layer insulation layer 15 are sequentially formed. Then, a passivation layer 17 is formed over the third inter-layer insulation layer 15. Herein, the second metal interconnection line 16 includes a metal pattern 16A and a titanium (Ti)/titanium nitride (TiN) layer 16B used as a barrier layer.

Next, to form a fuse box, i.e., to make an insulation layer remain with a predetermined thickness, in an upper portion of the fuses 12, the first inter-layer insulation layer 13 and the second inter-layer insulation layer 14 formed over the fuses 12 are selectively removed.

The first inter-layer insulation layer 13 is formed by stacking a plasma enhanced tetraethyl orthosilicate (PETEOS) layer and a hydrogen silsesquioxane (HSQ) layer. The second inter-layer insulation layer 14 is formed by using a semi-recessed oxide (SROₓ) layer. The passivation layer 17 is formed by using a high density plasma (HDP) oxide layer or a plasma enhanced (PE) nitride layer.

During a pad/repair process for forming the fuse box, the passivation layer 17 is etched in a magnetically enhanced reactive ion etching (MERIE) type plasma etching apparatus by using a gas including CHFₓ, CₓFₓ, O₂, CO and Ar, which are mixed in a ratio of approximately 5 parts of CHFₓto approximately 5 parts of CₓFₓto approximately 1 part of O₂ to approximately 30 parts of CO to approximately 20 parts of Ar. At this time, a pressure ranging from approximately 10 mTorr to approximately 100 mTorr and a power ranging from approximately 1,000 W to approximately 2,000 W are used.

Next, the third inter-layer insulation layer 15 and the second inter-layer insulation layer 15 are etched to remove the Ti/TiN layer 16B formed over the metal pattern 16A using a recipe that an etch selectivity ratio of the third and fourth inter-layer insulation layers 15 and 14 (e.g., a SROₓ, layer) to the Ti/TiN layer 16B is approximately 2 to approximately 7: approximately 1. Thus, during the etching of the second inter-layer insulation layer 14 and the third inter-layer insulation layer 15 to a thickness of approximately 1,000 Å, the etching process is controlled to make the second inter-layer insulation layer 14 and the third inter-layer insulation layer 15 remain with a thickness ranging from approximately 2,000 Å to approximately 3,000 Å over the fuses 12 while completely removing the Ti/TiN layer 16B formed over the metal pattern 16A for the pad.

If the fuse box is formed using the above described typical process condition, although an amount of an etch gas, a power and a pressure are controlled, it is difficult to obtain the etch selectivity of the second inter-layer insulation layer 14 to the Ti/TiN layer 16B equal to or less than a ratio of approximately 10 to approximately 1.

As shown in FIG. 2, a Ti/TiN layer formed over fuses inside the fuse box is more thickly formed than a metal pattern for a pad by a thickness ranging from approximately 1,000 Å to approximately 2,000 Å. Accordingly, in case of considering a height which a second inter-layer insulation layer and the Ti/TiN layer are etched respectively, it may be difficult to completely remove the Ti/TiN layer and make the second inter-layer insulation layer remain over the upper portion of the fuses with a predetermined thickness.

Moreover, as shown in FIG. 3, during a pad/repair process, a lower structure is formed to have a profile proportionate with a height to be etched as reference denotation X illustrates. However, it may be difficult to form an appropriate fuse box.

After the pad/repair process for making an insulation layer remain with a predetermined thickness over an upper portion of fuses inside a fuse box, as shown in FIG. 4, a metal pattern for a pad is often not opened as reference denotation Y illustrates.

Furthermore, as show in FIG. 5, if a pad/repair process is performed to sufficiently open the metal pattern for the pad, the fuse box may be etched too much and thus, the fuses may be damaged. Reference denotation Z illustrates the damaged fuses.

### SUMMARY OF THE INVENTION

It is, therefore, an object of the present invention to provide a method for fabricating a semiconductor device capable of reliably opening a metal pattern for a pad during a pad/repair process and preventing fuses from being damaged.

In accordance with one aspect of the present invention, there is provided a method for fabricating a semiconductor device, including: forming a first insulation layer over a substrate; forming a plurality of fuses over the first insulation layer; forming a second insulation layer to cover the fuses; forming an etch stop layer over the second insulation layer; forming a metal layer over a predetermined portion of the etch stop layer; forming a third insulation layer to cover the metal layer; performing a pad/repair process on the third insulation layer until the metal layer and the etch stop layer are exposed; and selectively removing the exposed portion of the etch stop layer and the second insulation layer.

### BRIEF DESCRIPTION OF THE DRAWINGS

The above and other objects and features of the present invention will become better understood with respect to the following description of the preferred embodiments given in conjunction with the accompanying drawings, in which:

FIG. 1 is a cross-sectional view illustrating a conventional method for fabricating a semiconductor device;

FIGS. 2 to 5 are micrographic images of scanning electron microscopy (SEM) illustrating a conventional semiconductor device; and

FIGS. 6A to 6C are cross-sectional views illustrating a method for fabricating a semiconductor device in accordance with a specific embodiment of the present invention.

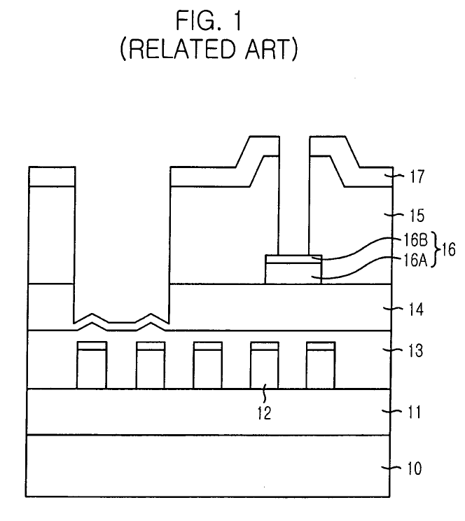

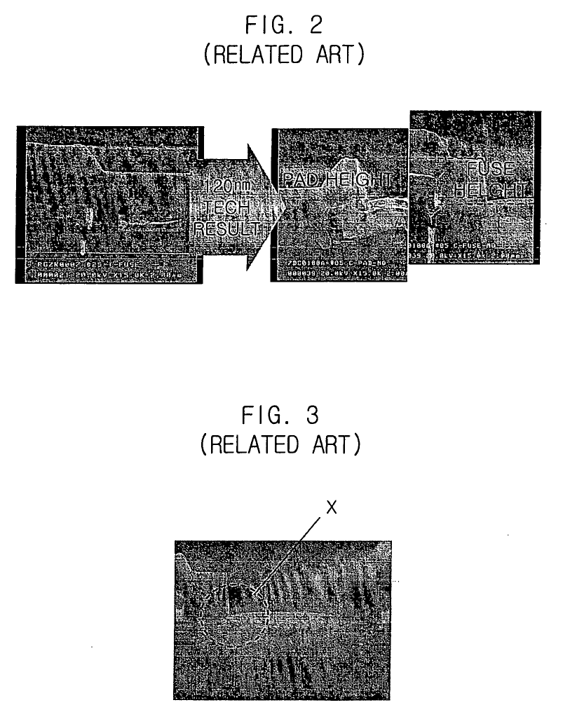

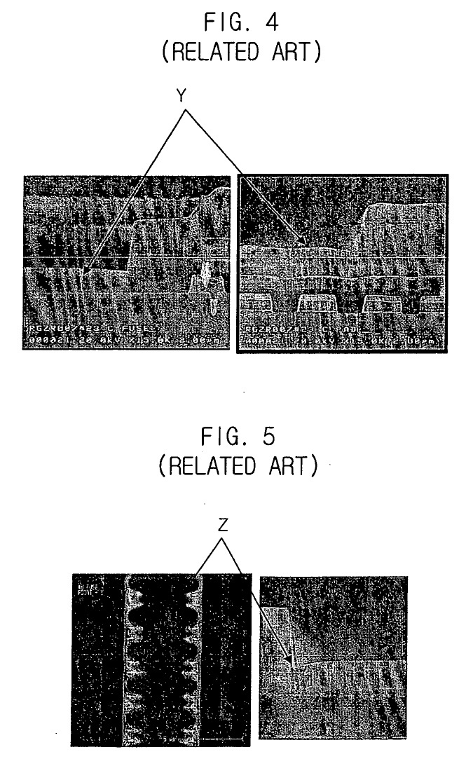

### DETAILED DESCRIPTION OF THE INVENTION

Hereinafter, detailed descriptions on certain embodiments of the present invention will be provided with reference to the accompanying drawings.

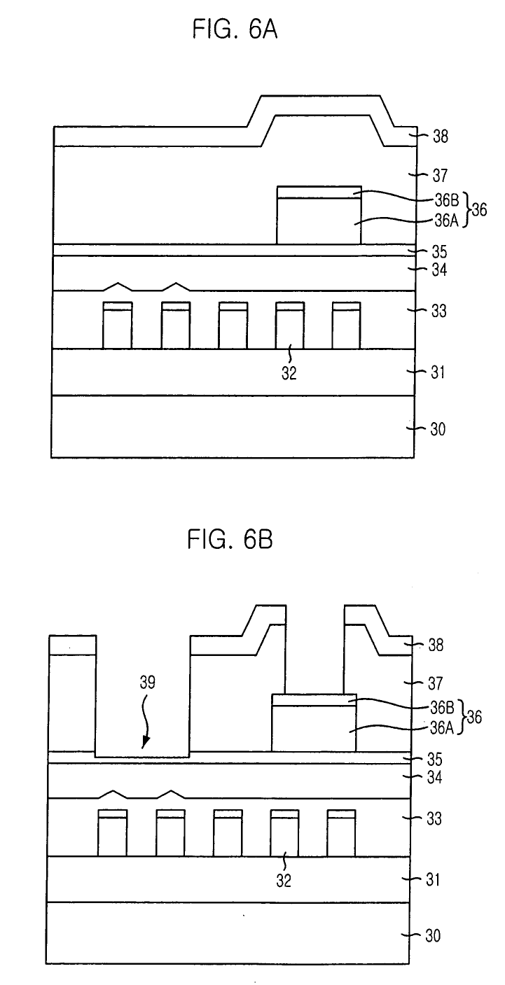

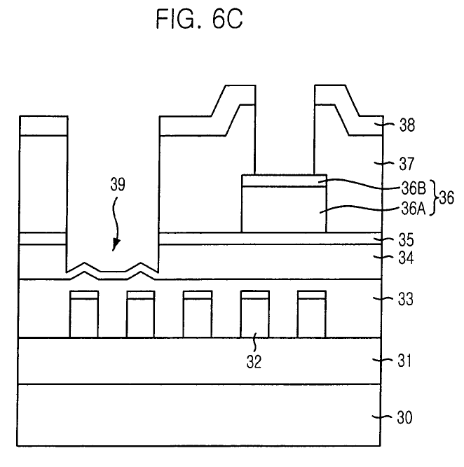

FIGS. 6A to 6C are cross-sectional views illustrating a method for fabricating a semiconductor device in accordance with a specific embodiment of the present invention.

As shown in FIG. 6A, a first insulation layer 31 is formed over a substrate 30.

Next, a plurality of fuses 32 are formed by using a first metal interconnection line over the first insulation layer 31. A second insulation layer 33 and a third insulation layer 34 are sequentially formed thereon. An etch stop layer 35 is formed on an upper portion of the third insulation layer 34.

Next, a metal layer 36 including a metal pattern 36A for a pad and a titanium (Ti)/titanium nitride (TiN) layer 36B is formed by using a second metal interconnection line, and a fourth insulation layer 37 and a passivation layer 38 are formed thereon.

Next, as shown in FIG. 6B, a pad/repair process is performed to expose a pad part (i.e., the metal layer 36) and a fuse part. That is, the Ti/TiN layer 36B formed over an upper portion of the metal layer 36 for the pad is exposed, and a fuse box 39 is formed in the fuse part. The pad/repair process utilizes an etching process, and the etching process is stopped at the etch stop layer 35 formed over the fuses 32 in the fuse part.

Next, as shown in FIG. 6C, the exposed portion of the etch stop layer 35 and the third insulation layer 34 are selectively removed. Thus, a predetermined thickness of the insulation layers remains over the fuses 32.

Hereinafter, the above described process will be explained in more details.

First, the fuses 32 are formed by using a metal layer. A plasma enhanced tetraethyl orthosilicate (PETEOS) layer, a hydrogen silsesquioxane (HSQ) layer, and a semi-recessed oxide (SROx) layer are deposited as the second insulation layer 33 and the third insulation layer 34. The etch stop layer 35 is formed in a thickness ranging from approximately 500 Å to approximately 2,000 Å by using a plasma enhanced (PE) nitride layer.

Then, the metal layer 36, which is formed by stacking the metal pattern 36A and the Ti/TiN layer 36B over the etch stop layer 35 serves as a pad. The passivation layer 38 is formed by using a high density plasma (HDP) oxide layer or a plasma enhanced (PE) nitride layer.

Next, the aforementioned pad/repair process (e.g., an etching process) is performed to remove the passivation layer 38 and the fourth insulation layer 37 so that the fuse part and the pad part are exposed. The pad/repair process is performed in a magnetically enhanced reactive ion etch (MERIE) type etching apparatus by using a gas including CHₓF_{y}, CₓF_{y}, O₂, and Ar, which is mixed in a ratio of approximately 2 parts of CHₓF_{y} to approximately 6 parts of CₓF_{y} to approximately 1 part of O₂ to approximately 25 parts of Ar. Also, the pad/repair process is performed using a pressure ranging from approximately 10 mTorr to approximately 100 mTorr and a power ranging from approximately 500 W to approximately 2,000 W. Particularly, the passivation layer 38 and the fourth insulation layer 37 have a high etch selectivity with respect to the etch stop layer 38. As an exemplary process condition for the pad/repair process, a pressure of approximately 25 mTorr and a power of approximately 1,400 W are applied. At this time, the Ar gas, the C₄F₈ gas, the CH₂F₂ gas, and the O₂ gas are flowed with a respective quantity of approximately 400 sccm, approximately 13 sccm, approximately 5 sccm and approximately 3 sccm.

The etching process (i.e., the pad/repair process) is stopped at the etch stop layer 35 formed over the fuses 32 in the fuse part, and the Ti/TiN layer 36B is opened in the pad part. At this time, it is possible to use one selected from the group consisting of IPS, an inductively coupled plasma (ICP) type etching apparatus, a transformer coupled plasma (TCP) type etching apparatus, an electron cyclotron resonance (ECR) type etching apparatus, a magnetically enhanced reactive ion etching (MERIE) type apparatus.

Afterwards, the etch stop layer 35 in the fuse part may be removed in a MERIE type etching apparatus under a condition of: a gas including CₓF_{y}, CHₓ,F_{y}, O₂ and Ar mixed in a ratio of approximately 9 parts of CₓF_{y} to approximately 1 part of CHₓF_{y} to approximately 30 parts of O₂ to approximately 20 parts of Ar; and a pressure ranging from approximately 10 mTorr to approximately 100 mTorr. Under this process condition, the etch stop layer 35 may be etched to a thickness ranging from approximately 1,000 Å to approximately 2,000 Å, and in this case, it is possible to uniformly control a thickness of the insulation layers remaining over the upper portion of the fuses 32 and stably form the pad as compared with the conventional method. For instance, the etching process (i.e., the pad/repair process) may be performed in a condition including a pressure of approximately 40 mTorr, and a power of approximately 1,600 W.

In accordance with the specific embodiment of the present invention, forming fuses by using a first metal layer and a pad by using a second metal layer under the above described conditions make it possible make an insulation layer remain with a predetermined thickness over the upper portion of the fuses and to stably expose the pad.

Accordingly, the scale of integration, yields of products, and productivity can be improved. Therefore, related costs can be reduced.

The present application contains subject matter related to the Korean patent application No. KR 2005-58711, filed in the Korean Patent Office on Jun. 30, 2005 the entire contents of which being incorporated herein by reference.

While the present invention has been described with respect to certain preferred embodiments, it will be apparent to those skilled in the art that various changes and modifications may be made without departing from the spirit and scope of the invention as defined in the following claims.

What is claimed is:

1. A method for fabricating a semiconductor device, comprising:
forming a first insulation layer over a substrate;
forming a plurality of fuses over the first insulation layer;
forming a second insulation layer to cover the fuses;
forming an etch stop layer over the second insulation layer;
forming a metal layer over a predetermined portion of the etch stop layer;
forming a third insulation layer to cover the metal layer;
performing a pad/repair process on the third insulation layer until the metal layer and the etch stop layer are exposed; and
selectively removing the exposed portion of the etch stop layer and the second insulation layer.

2. The method of claim 1, wherein the metal layer serves as a pad.

3. The method of claim 1, wherein the etch stop layer includes a plasma enhanced nitride layer.

4. The method of claim 1, wherein the fuses include a metal layer used as a first metal interconnection line.

5. The method of claim 1, wherein the metal layer includes a second metal interconnection line.

6. The method of claim 1, wherein the pad/repair process is performed by using a gas including CₓF_{y}, CHₓF_{y}, O₂ and Ar, which is mixed in a ratio of approximately 6 parts of CₓF_{y} to approximately 2 parts of CHₓF_{y} to approximately 1 part of O₂ to approximately 25 parts of Ar.

7. The method of claim 1, wherein the pad/repair process is performed by using a pressure ranging from approximately 10 mTorr to approximately 100 mTorr.

8. The method of claim 1, wherein the pad/repair process is performed by using a power ranging from approximately 500 W to approximately 2,000 W.

9. The method of claim 1, wherein the pad/repair process is performed under a condition that the third insulation layer has a high etch selectivity to the etch stop layer.

10. The method of claim 1, wherein the etch stop layer is formed in a thickness ranging from approximately 500 Å to approximately 2,000 Å.

11. The method of claim 1, wherein the removing of the exposed portion of the etch stop layer comprises using a gas including CₓF_{y}, CHₓF_{y}, O₂ and Ar, which is mixed in a ratio of approximately 9 parts of CₓF_{y} to approximately 1 part of CHₓF_{y} to approximately 30 parts of O₂ to approximately 20 parts of Ar.

12. The method of claim 1, wherein the removing of the exposed portion of the etch stop layer comprises using a pressure ranging from approximately 10 mTorr to approximately 100 mTorr.
